(19) United States
(12) Patent Application Publication
(10) Pub. No.: US 2026/0354161 A1
(43) Pub. Date: Nov. 5, 2026

(54) SYSTEM ON INTEGRATED CHIPS AND METHODS OF FORMING

(71) Applicant: Taiwan Semiconductor Manufacturing Co., Ltd., Hsinchu (TW)

(72) Inventors: Kuo-Chiang Ting, Hsinchu (TW); Sung-Feng Yeh, Taipei City (TW); Ta Hao Sung, Hsinchu (TW); Shin-Jiun Fu, Hsinchu (TW)

(21) Appl. No.: 19/741,372

(22) Filed: Jul. 14, 2026

Related U.S. Application Data
(63) Continuation of application No. 19/003,743, filed on Dec. 27, 2024.
(60) Provisional application No. 63/694,249, filed on Sep. 13, 2024.

(51) Int. Cl. H10W 20/43; H10W 20/20; H10W 20/40; H10W 72/00; H10W 74/10; H10W 90/00

(52) U.S. Cl. CPC H10W 20/43; H10W 20/20; H10W 20/495; H10W 74/141; H10W 72/0198; H10W 90/792

(57) ABSTRACT

A semiconductor device (e.g., a System on Integrated Chip (SoIC) device) is formed by vertically integrating (e.g., bonding) semiconductor dies, where each of the semiconductor dies has a front-side interconnect structure and has a backside interconnect structure. A front-side to front-side bonding process is used to bond the integrated semiconductor dies, which reduces the lengths of the communication paths between the integrated semiconductor dies. The reduced lengths of the communication paths reduce the electrical resistance and the signal transmission delay of the communication paths, thus improving the processing speed of the semiconductor device and reducing power consumption. In addition, the bonding film stack around the bonding structure of the semiconductor dies can be formed thinner, which reduces the risk of metal cracking, thus improving device reliability and production yield.

### PRIORITY CLAIM AND CROSS-REFERENCE

This application is a continuation of U.S. patent application Ser. No. 19/003,743, filed Dec. 27, 2024 and entitled “System on Integrated Chips and Methods of Forming,” which application claims priority to U.S. Provisional Application No. 63/694,249, filed Sep. 13, 2024 and entitled “SPR on SoIC Signal to Signal Bonding W/BPV Landing on Metal Structure,” which applications are hereby incorporated by reference in their entireties.

### BACKGROUND

Semiconductor devices are used in a variety of electronic applications, such as personal computers, cell phones, digital cameras, and other electronic equipment, as examples. Semiconductor devices are typically fabricated by depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area. As feature sizes continue to shrink in advanced semiconductor manufacturing nodes, new challenges arise that must be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4 illustrate cross-sectional views of a semiconductor die at various stages of manufacturing, in accordance with an embodiment.

FIG. 5 illustrates a cross-sectional view of a wafer, in accordance with an embodiment.

FIGS. 6-8 illustrate cross-sectional views of a semiconductor device at various stages of manufacturing, in accordance with an embodiment.

FIGS. 9A and 9B illustrate example cross-sectional views of a bonding structure, in accordance with some embodiments.

FIGS. 10-11 illustrate cross-sectional views of a semiconductor device at various stages of manufacturing, in accordance with another embodiment.

FIGS. 12-16 illustrate cross-sectional views of a semiconductor device at various stages of manufacturing, in accordance with yet another embodiment.

FIG. 17 illustrates a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. Throughout the description, unless otherwise specified, the same or similar reference numerals in different figures refer to the same or similar component formed by a same or similar method using a same or similar material(s).

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a semiconductor device (e.g., a System on Integrated Chip (SoIC) device) is formed by vertically integrating (e.g., bonding) semiconductor dies, where each semiconductor die has a backside power distribution network (PDN) formed by a backside interconnect structure. A front-side to front-side bonding process is used to bond the integrated semiconductor dies, which reduces the lengths of the communication paths between the integrated semiconductor dies. The reduced lengths of the communication paths reduce the electrical resistance and the signal transmission delay of the communication paths, thus improving the processing speed of the semiconductor device and reducing power consumption. In addition, the bonding film stack around the bonding structure of the semiconductor dies can be formed thinner, which reduces the risk of metal cracking, thus improving device reliability and production yield.

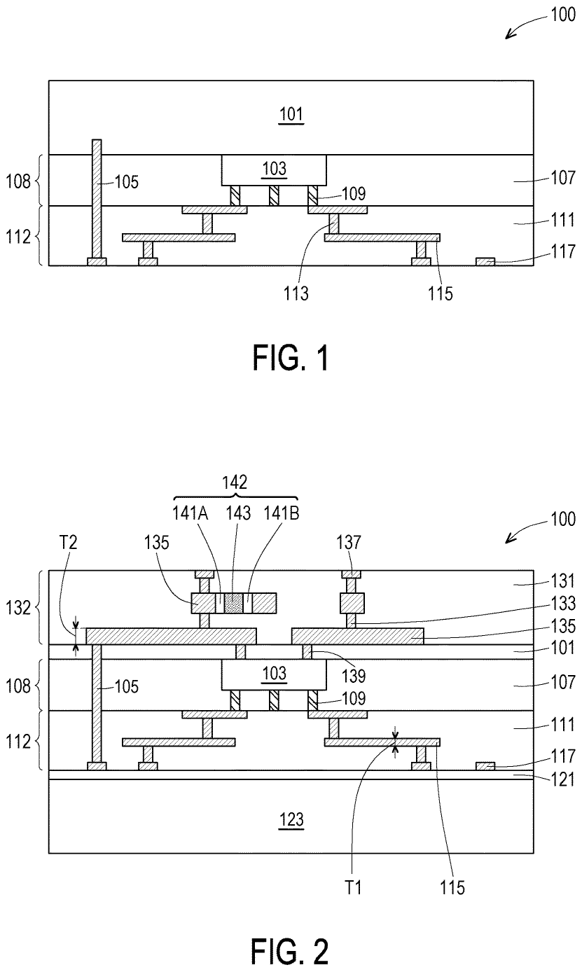

FIGS. 1-4 illustrate cross-sectional views of a semiconductor die 150 at various stages of manufacturing, in accordance with an embodiment. As will be discussed in detail hereinafter, multiple semiconductor dies 150 are formed on a wafer 100, and the wafer 100 is then singulated by a dicing process to form multiple individual (e.g., separate) semiconductor dies 150.

FIG. 1 illustrates a cross-sectional view of a wafer 100 at an early stage of manufacturing. For simplicity, only a portion of the wafer 100 is illustrated, and not all features of the wafer 100 are illustrated. The illustrated portion of the wafer 100 may correspond to one of the semiconductor dies (see 150 in FIG. 4) formed on the wafer 100.

As illustrated in FIG. 1, the wafer 100 comprises a substrate 101, electrical components 103 formed on the substrate 101, one or more dielectric layers 107 over the substrate 101 and around the electrical components 103, and interconnect structures 112 over the one or more dielectric layers 107.

The substrate 101 may be a semiconductor substrate (e.g., a silicon substrate), doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates. In an embodiment, the substrate 101 is a silicon substrate (e.g., a bulk silicon substrate).

The electrical components 103 comprise a wide variety of active devices (e.g., transistors) and passive devices (e.g., capacitors, resistors, inductors), and the like. The electrical components 103 may be formed using any suitable method either within or on the substrate 101. For example, the electrical components 103 may comprise fin field-effect transistors (FinFETs) that include fins that protrude above the substrate 101, gate structures over the fins, and source/drain regions over the fins on opposing sides of the gate structures. As another example, the electrical components 103 may comprise nanostructure field-effect transistors (NSFETs) (e.g., gate-all-around (GAA) transistors) that include fins that protrudes above the substrate 101, nanostructures (e.g., nanosheets or nanowires) over the fins, gate structures around the nanostructures, and source/drain regions over the fins on opposing sides of the gate structures.

One or more dielectric layers 107, such as one or more inter-layer dielectric (ILD) layers (e.g., a first ILD layer and a second ILD layer), are formed over the substrate 101 and around the electrical components 103. In some embodiments, each of the ILD layers is formed of a dielectric material such as silicon oxide, phosphosilicate glass (PSG), borosilicate glass (BSG), boron-doped phosphosilicate Glass (BPSG), undoped silicate glass (USG), or the like, and may be deposited by any suitable method, such as chemical vapor deposition (CVD), plasma-enhanced CVD (PECVD), flowable CVD (FCVD) (e.g., a CVD-based material deposition in a remote plasma system and post curing to make it convert to another material, such as an oxide), or the like.

FIG. 1 further illustrates contact plugs 109 (e.g., vias) formed in the one or more dielectric layers 107, such as source/drain contact plugs and gate contact plugs that are electrically coupled to the source/drain regions and gate structures of the transistors, respectively. The contact plugs 109 may be formed by, e.g., forming contact openings in the one or more dielectric layers 107, and filling the contact openings with an electrically conductive material (e.g., tungsten, cobalt, copper, or the like). A liner material, such as titanium, titanium nitride, tantalum, tantalum nitride, may be formed to line the sidewalls of the contact openings before the electrically conductive material fills the contact openings. After the contact openings are filled, a planarization process, such as a chemical mechanical planarization (CMP) process, may be performed to achieve a coplanar surface between the contact plugs 109 and the one or more dielectric layers 107. To facilitate discussion herein, the electrical components 103, the contact plugs 109, and the one or more dielectric layers 107 may be collectively referred to as a device layer 108.

Next, interconnect structures 112 (also referred to as front-side interconnect structures) are formed on the one or more dielectric layers 107. The interconnect structure 112 of each semiconductor die interconnects the respective electrical components 103 of the semiconductor die to form a functional circuit of the semiconductor die. The interconnect structure 112 includes one or more dielectric layer 111 and conductive features (e.g., conductive lines 115 and vias 113) formed in the one or more dielectric layers 111. The one or more dielectric layer 111 may be formed of a suitable dielectric material, such as silicon oxide, silicon nitride, low-k dielectrics such as carbon doped oxides, extremely low-k dielectrics such as porous carbon doped silicon dioxide, combinations of these, or the like. The one or more dielectric layers 111 may be formed through a process such as CVD, although any suitable process may be utilized. The conductive lines 115 and the vias 113 may be formed of a conductive material such as copper, using any suitable formation method, such as deposition, damascene, dual damascene, or the like. Note that in the discussion herein, unless otherwise specified, the term “conductive” means electrically conductive (e.g., instead of thermally conductive).

FIG. 1 further illustrates conductive patterns 117 formed at a surface of the interconnect structure 112 distal from the substrate 101. The conductive patterns 117 may be, e.g., conductive pads such as copper pads. In addition, FIG. 1 illustrates through-silicon-vias (TSVs) 105. In the illustrated embodiment, the TSVs 105 extend from the conductive patterns 117, through the interconnect structure 112, through the device layer 108, and into the substrate 101. Note that the TSVs 105 extend into, but not through, the substrate 101 at this stage of processing in FIG. 1.

Next, in FIG. 2, a carrier substrate 123 (may also be referred to as a carrier) is attached to the interconnect structure 112. The carrier substrate 123 (or other carrier substrate discussed hereinafter) is a silicon substrate (e.g., a bulk silicon substrate such as a silicon wafer), and does not have electrical components formed therein, in some embodiments. Besides silicon substrate, any other suitable carrier substrate may also be used. The carrier substrate 123 may be attached to the interconnect structure 112 using an adhesive layer 121.

Next, a thinning process is performed to reduce the thickness of the substrate 101, such that end surfaces of the TSVs 105 are exposed at a surface of the substrate 101 facing away from the carrier substrate 123. The thinning process may comprise a planarization process (e.g., a mechanical grinding, a CMP, or the like), an etch-back process, a combination thereof, or the like. In some embodiments, after the thinning process, the thickness of the substrate 101 is less than about 100 nm.

Next, interconnect structures 132 (also referred to as backside interconnect structures) are formed at the backside of the substrate 101. The interconnect structure 132 includes one or more dielectric layers 131 and conductive features (e.g., conductive lines 135 and vias 133) formed in the one or more dielectric layers 131. The one or more dielectric layers 131 and conductive features (e.g., conductive lines 135 and vias 133) of the interconnect structure 132 may be formed of a same or similar material(s) using a same or similar formation method as the one or more dielectric layers 111 and the conductive features (e.g., conductive lines 115 and vias 113) of the interconnect structure 112, thus details are not repeated.

As illustrated in FIG. 2, the conductive features of the interconnect structure 132 are electrically coupled to the electrical components 103 and the TSVs 105. For example, vias 139 may be formed to extend through the substrate 101 and electrically couple the conductive features of the interconnect structure 132 to the electrical components 103. In some embodiments, the vias 139 extend from the backside of the substrate 101 to the front side of the substrate 101, and are electrically coupled to, e.g., source/drain regions and/or gate structures of the transistors of the electrical components 103. In the discussion herein, the front-side of the substrate 101 refers to the side of the substrate 101 facing the electrical components 103, and the backside of the substrate 101 refers to the side of the substrate 101 facing away from the electrical components 103.

As illustrated in FIG. 2, the TSVs 105, which extend through the thinned substrate 101, are electrically coupled to conductive features of the interconnect structure 132. Conductive patterns 137 (e.g., copper pads) of the interconnect structure 132 are formed at a surface of the interconnect structure 132 facing away from the substrate 101.

In some embodiments, the conductive lines 135 of the backside interconnect structures 132 are power rails, which are conductive lines that electrically connect the electrical components 103 to a reference voltage (e.g., electrical ground), a supply voltage (e.g., +1.5V, +3V, +5V, or the like), or the like. In other words, unlike the front-side interconnect structure 112 which routes data signals and control signals, the backside interconnect structure 132 is used to route power signals (e.g., supply voltage, reference voltage), in some embodiments. By placing power rails on the backside of the resulting semiconductor die rather than on the front-side of the semiconductor die, advantages may be achieved. For example, a gate density of the FinFETs (or NSFETs) and/or interconnect density of the front-side interconnect structure 112 may be increased. Further, the backside of the semiconductor die may accommodate wider power rails, thus reducing resistance and increasing efficiency of power delivery to the electrical components 103. For example, a width T₂ of the conductive lines 135 of the backside interconnect structure 132 may be at least twice a width T₁ of the conductive lines 115 of the front-side interconnect structure 112.

In the example of FIG. 2, the backside interconnect structure 132 further includes capacitors 142 formed between laterally adjacent conductive lines 135. In an embodiment, each capacitor 142 includes a first barrier layer 141A along a first sidewall of a first conductive line 135, a second barrier layer 141B along a second sidewall of a second conductive line 135 laterally adjacent to the first conductive line 135, and a high-k dielectric material 143 between the first barrier layer 141A and the second barrier layer 141B. The high-k dielectric material 143 fills the space between the first barrier layer 141A and the second barrier layer 141B completely (e.g., extends continuously from the first barrier layer 141A to the second barrier layer 141B).

The first barrier layer 141A and the second barrier layer 141B may be formed of a conductive material such as tantalum nitride, titanium nitride, tantalum, titanium, or the like, and function as the electrodes of the capacitor 142. The high-k dielectric material 143 may have a k-value great than about 7.0 (e.g., between about 7.0 and about 40), and may include metal oxides or silicates of hafnium, aluminum, zirconium, lanthanum, manganese, barium, titanium, lead, and combinations thereof. The high-k dielectric material 143 functions as the dielectric medium between the electrodes of the capacitor 142. The capacitor 142 may be referred to a metal-insulator-metal (MIM) capacitor, or an MIM capacitor embedded in the backside interconnect structure 132. In some embodiments, the backside interconnect structure 132 is used to distribute power for the semiconductor device formed, and may be referred to as backside power distribution network (PDN). The embedded MIM capacitors 142 may be used to form power circuits and/or to stabilize voltages (e.g., reference voltages, supply voltages) in the PDN, thus achieving improved performance for the device formed.

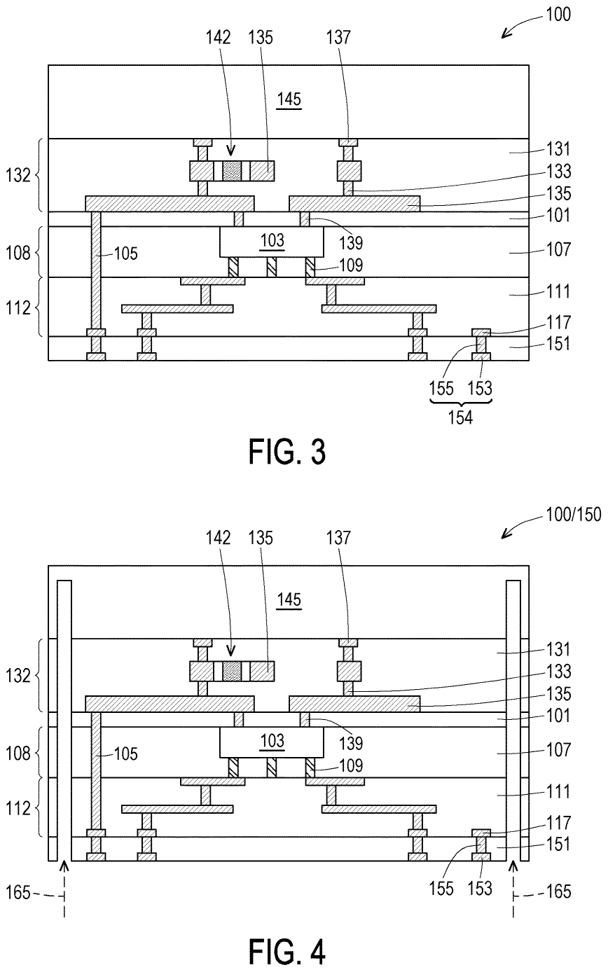

Next, in FIG. 3, a carrier substrate 145 is attached to the backside interconnect structure 132. In some embodiments, an adhesive layer (not separately illustrated) is used to attach the carrier substrate 145 to the backside interconnect structure 132. Next, the carrier substrate 123 (see FIG. 2) is removed by, e.g., mechanically peeling off the carrier substrate 123, a grinding process, an etching process, combinations thereof, or the like. The adhesive layer 121 may be removed together with the carrier substrate 123. In some embodiments, after the carrier substrate 123 is removed, residues of the adhesive layer 121 are removed by a cleaning process (e.g., an etching process), such that the conductive patterns 117 are exposed at the surface of the front-side interconnect structure 112 distal from the substrate 101.

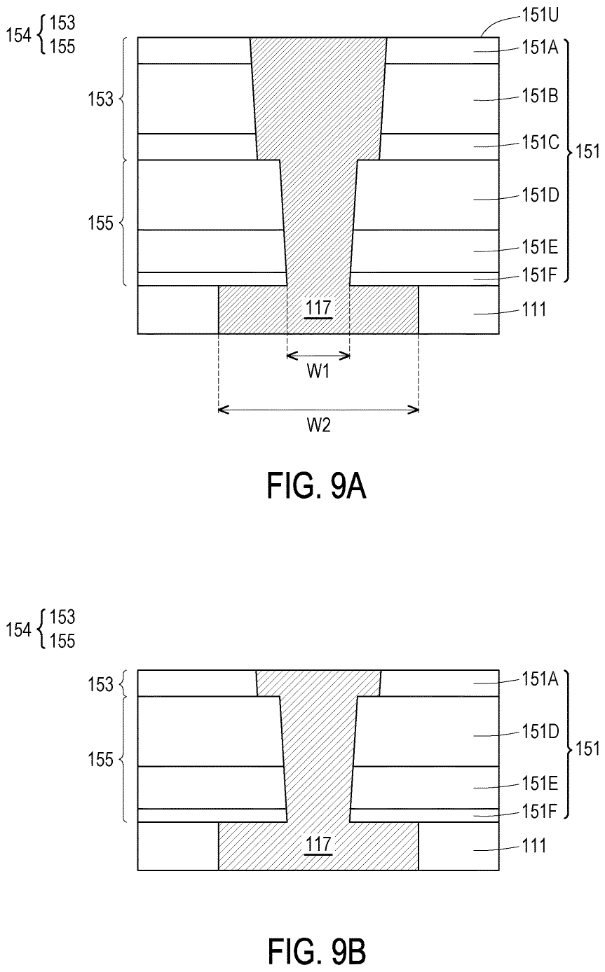

Next, a bonding film stack 151 is formed on the front-side interconnect structure 112, and bonding structures 154 are formed (e.g., embedded) in the bonding film stack 151. In some embodiments, the bonding film stack 151 includes a plurality of dielectric layers, and each of the bonding structures 154 includes a bonding pad 153 and a bonding pad via (BPV) 155. The bonding pad 153 (e.g., a copper pad) may have a coplanar surface with the bonding film stack 151, which coplanar surface faces away from the substrate 101. The BPV 155 (e.g., a copper via) is interposed between, and electrically couples, the bonding pad 153 and a respective conductive pattern 117 of the front-side interconnect structure 112. Note that some of the bonding structures 154 are electrically coupled to the TSVs 105. Examples of the bonding structure 154 and the bonding film stack 151 are shown in FIGS. 9A and 9B.

Referring temporarily to FIG. 9A, which illustrates an example of the bonding structure 154 and the bonding film stack 151. To illustrate the electrical connection of the bonding structure 154, the conductive pattern 117 and one of the dielectric layers 111 of the front-side interconnect structure 112 are also illustrated in FIG. 9A, with the understanding that the conductive pattern 117 and the dielectric layers 111 are not part of the bonding structure 154 or the bonding film stack 151.

In the example of FIG. 9A, the bonding film stack 151 includes a bonding film 151A, a dielectric layer 151B, a dielectric layer 151C, a dielectric layer 151D, a dielectric layer 151E, and an etch stop layer (ESL) 151F. The bonding pad 153 of the bonding structure 154 is formed (e.g., embedded) in the bonding film 151A, the dielectric layer 151B, and the dielectric layer 151C. The BPV 155 is formed (e.g., embedded) in the dielectric layer 151D, the dielectric layer 151E, and the ESL 151F. In other words, the upper surface of the bonding pad 153 is level with the upper surface of the bonding film 151A, and the lower surface of the bonding pad 153 is level with the lower surface of the dielectric layer 151C. Similarly, the upper surface of the BPV 155 is level with the upper surface of the dielectric layer 151D, and the lower surface of the BPV 155 is level with the lower surface of the ESL 151F.

In some embodiments, the bonding pad 153 and the BPV 155 are formed by performing a plurality of etching processes to form a pad opening and a via opening in the respective layers of the bonding film stack 151, and filling the pad opening and the via opening with a conductive material (e.g., copper). A planarization process, such as CMP, may be performed next to remove excess portions of the conductive material disposed outside of the pad opening and the via opening. The remaining portions of the conductive material in the pad opening and the via opening form the bonding pad 153 and the BPV 155, respectively.

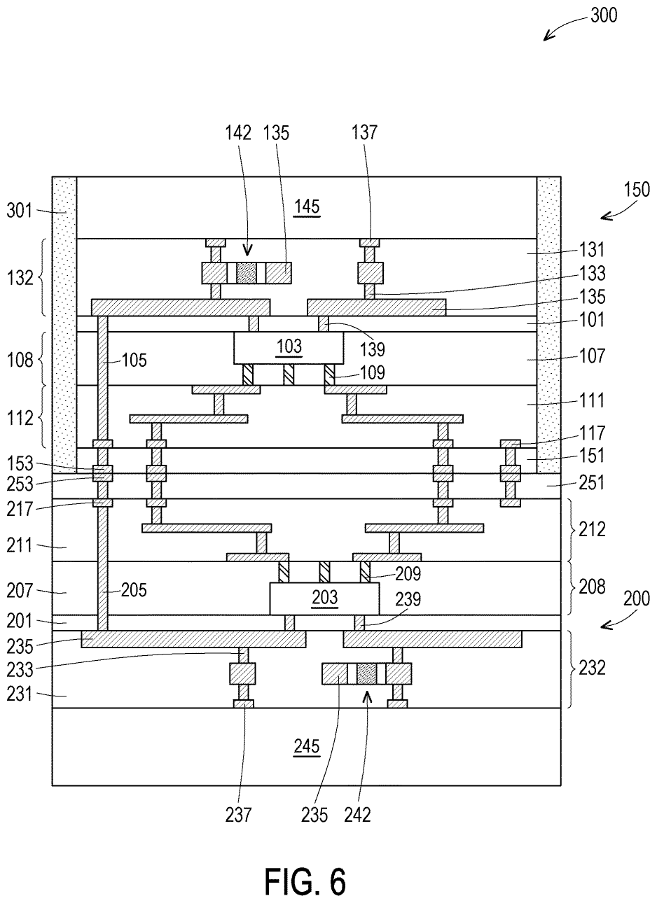

In some embodiments, each of the bonding film 151A and the dielectric layers 151B-151E is formed using a suitable dielectric material, such as SiO₂, SiN, SiON, SiC, SiCN, SiCO, AlN, GaN, ZnO, BN, Al₂Oₓ, HfO₂, or TiO₂. The ESL 151F may be formed using, e.g., hydrogen and nitrogen doped carbide (HNDC) or SiN. In some embodiments, adjacent layers of the bonding film stack 151 are formed of different dielectric materials to provide etching selectivity between the adjacent layers for easy control (e.g., control of etching stop point) of the etching processes used to form the pad opening and the via opening. In addition, materials of the top dielectric layers in the bonding film stack 151, such as the bonding film 151A and the dielectric layers 151B and 151C, may be chosen to control the warpage of the upper surface 151U of the bonding film stack 151 and to achieve certain profile (e.g., a flat surface, or a concave or convex surface with certain curvature). In subsequent processing, the wafer 100 is singulated into separate semiconductor dies 150, and the semiconductor dies 150 are attached (e.g., bonded) to a wafer 200 (see, e.g., FIG. 6) in a bonding process. In some embodiments, due to the process condition and/or the manufacturing tool used in the bonding process, a certain profile of the semiconductor die 150 may be conducive to achieving reliable bonding between the semiconductor die 150 and the wafer 200. The materials of the top dielectric layers (e.g., 151A, 151B, and 151C) of the bonding film stack 151 may be advantageously chosen to achieve the certain profile for the bonding process in accordance with the profile of the bonding surface of the wafer 200. Furthermore, materials of the dielectric layers of the bonding film stack 151 are chosen to have good thermal conductivity to avoid or reduce issues such as warpage, delamination, or cracking caused by stress generated due to change in temperature.

In some embodiments, the thickness (e.g., measured along the vertical direction of FIG. 9A) of each dielectric layer of the bonding film stack 151 is between about 10 nm to about 1000 nm. The thickness of the conductive pattern 117 may be between about 70 nm and about 250 nm. A ratio between a width W₁ of the BPV 155, measured at an interface between the BPV 155 and the conductive pattern 117, and a width W₂ of the conductive pattern 117, is between about 0.025 and about 1 (e.g., 0.025≤W₁/W₂≤1).

FIG. 9B illustrates another example of the bonding structure 154 and the bonding film stack 151. In FIG. 9B, the bonding film stack 151 has a smaller number of dielectric layers than the bonding film stack 151 in FIG. 9A, and the bonding pad 153 in FIG. 9B is formed (e.g., embedded) in the bonding film 151A. In particular, the bonding film stack 151 in FIG. 9B includes the bonding film 151A, the dielectric layers 151D and 151E, and the ESL 151F. The BPV 155 is formed (e.g., embedded) in the dielectric layer 151D, the dielectric layer 151E, and the ESL 151F. In some embodiments, the materials of adjacent dielectric layers in the bonding film stack 151 in FIG. 9B are different to provide etching selectivity, and the materials of the bonding film 151A and the dielectric layer 151D are chosen to achieve certain profile for the subsequently formed semiconductor dies 150, in order to achieve reliable bonding of the semiconductor dies 150, as discussed above.

Referring now to FIG. 4, after the processing of FIG. 3, a dicing process is performed to singulate the wafer 100 into a plurality of individual (e.g., separate) semiconductor dies 150 (may also be referred to as dies). The dicing process may be performed using, e.g., a plasma dicing process, along dicing regions (indicated by the dashed lines 165) around the semiconductor dies 150. The dicing process may start from the side of the wafer 100 having the bonding film stack 151 toward the carrier substrate 145. FIG. 4 illustrates trenches formed in the wafer 100 by the dicing process. The dicing process continues until the trenches extend through the carrier substrate 145, thus separating the wafer 100 into multiple separate semiconductor dies 150. In other words, after the dicing process is finished, the portion of the wafer 100 illustrated between the dashed lines 165 corresponds to a semiconductor die 150.

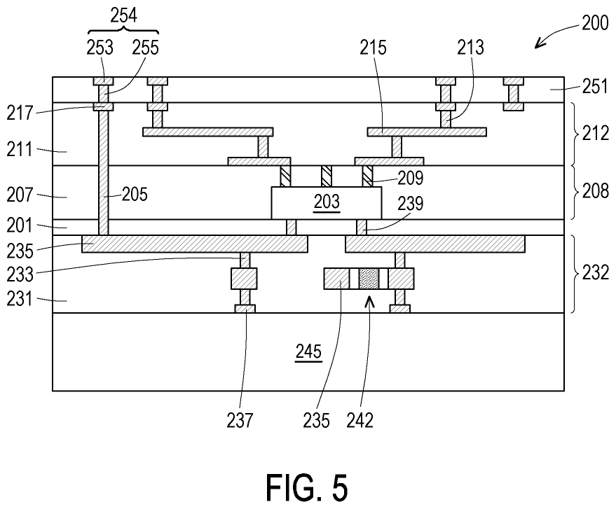

FIG. 5 illustrates a cross-sectional view of a wafer 200, in accordance with an embodiment. The wafer 200 is similar to the wafer 100 in FIG. 3, and may be formed using the same or similar formation method as the wafer 100, thus details are not repeated. In FIG. 5, a component with a numeral starting with the number “2” (e.g., 2XY) corresponds to the same or similar component in FIG. 3 with a numeral starting with the number “1” (e.g., 1XY). For example, the substrate 201 of the wafer 200 corresponds to the substrate 101 of the wafer 100. As another example, the front-side interconnect structure 212 of the wafer 200 corresponds to the front-side interconnect structure 112 of the wafer 100. As yet another example, the bonding structure 254 of the wafer 200 corresponds to the bonding structure 154 of the wafer 100. Note that in FIG. 5, the wafer 200 is shown with the carrier substrate 245 at the bottom of the figure, whereas in FIG. 3, the wafer 100 is shown with the carrier substrate 145 at the top of the figure.

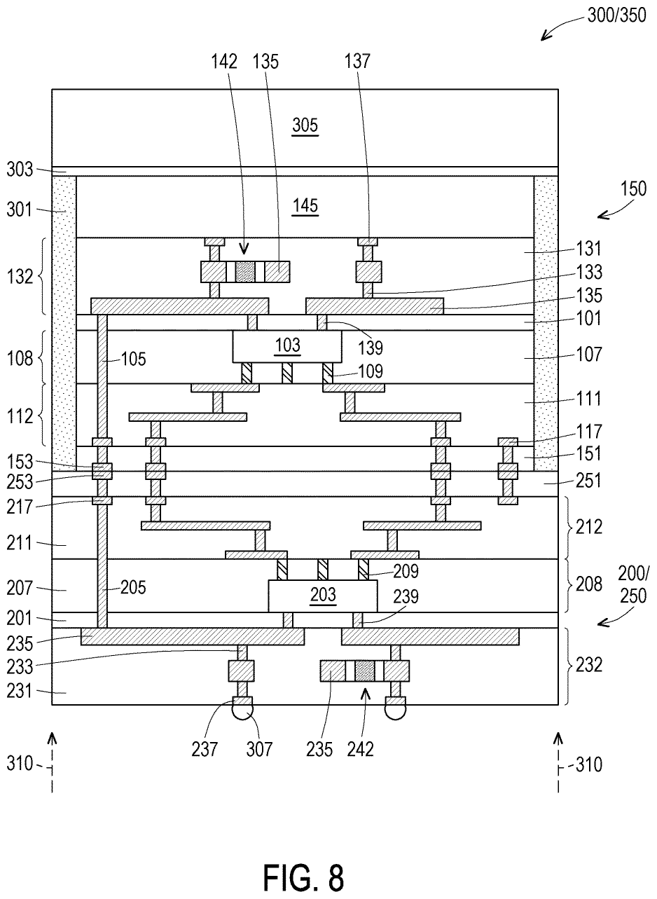

FIGS. 6-8 illustrate cross-sectional views of a semiconductor device 350 at various stages of manufacturing, in accordance with an embodiment. The semiconductor device 350 (see FIG. 8) may be, e.g., a System on Integrated Chip (SoIC) device. The semiconductor device 350 may also be referred to as a semiconductor package with vertically integrated semiconductor dies, or a semiconductor package. As will be described in detail hereinafter, the semiconductor dies 150 of FIG. 4 are attached to the wafer 200 to form a semiconductor structure 300. After certain processing of the semiconductor structure 300, a dicing process is performed to separate the semiconductor structure 300 into individual semiconductor devices 350.

Referring now to FIG. 6, the semiconductor dies 150 are attached (e.g., bonded) to the wafer 200 to form a semiconductor structure 300, which is referred to as a Chip on Wafer (CoW) structure at this stage of processing. Note that for simplicity, only a portion of the semiconductor structure 300 is illustrated in FIG. 6. The illustrated portion shows one semiconductor die 150 attached to the wafer 200, with the understanding that multiple semiconductor dies 150 are attached to the wafer 200.

In the illustrated embodiment of FIG. 6, the bonding pads 153 of each semiconductor die 150 are aligned with respective bonding pads 253 of the wafer 200 and bonded together. The bonding between the semiconductor die 150 and the wafer 200 may be a direct bonding without using a bonding material such as solder. For example, direct metal-to-metal bonding (between the bonding pads 153 and 253) and direct dielectric-to-dielectric bonding (between the bonding film stacks 151 and 251) may be used to bond the semiconductor die 150 to the wafer 200. In other embodiments, the semiconductor dies 150 are bonded to the wafer 200 through solder regions.

After bonding the semiconductor die 150 to the wafer 200, a thinning process is performed to reduce the thickness of the carrier substrate 145 of each semiconductor die 150. The thinning process may comprise a planarization process (e.g., a mechanical grinding, a CMP, or the like), an etch-back process, a combination thereof, or the like. Next, a gap-fill material 301 is formed over the wafer 200 and around the semiconductor dies 150. In some embodiments, the gap-fill material 301 is an oxide (e.g., silicon oxide) and may be formed by a suitable formation method such as CVD. Besides oxide, other suitable dielectric materials, such as a molding material, may also be used as the gap-fill material 301 to fill the gaps between the semiconductor dies 150. Next, a planarization process, such as CMP, may be performed to remove excess portions of the gap-fill material 301 from the upper surfaces of the carrier substrates 145, such that the gap-fill material 301 and the carrier substrates 145 have a coplanar upper surface. The gap-fill material 301 contacts (e.g., physically contacts) and extends along sidewalls of the semiconductor dies 150 and along an upper surface of the bonding film stack 251 distal from the substrate 201.

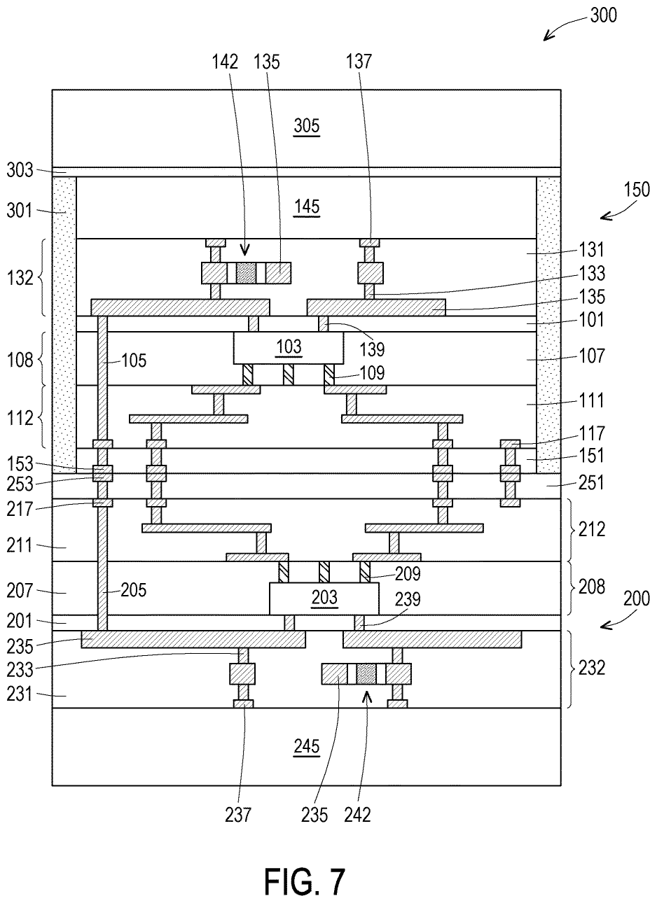

Next, in FIG. 7, a carrier substrate 305 is attached to the semiconductor structure 300 of FIG. 6. The carrier substrate 305 may be the same as or similar to the carrier substrate 145 (or 245), and may be another wafer (e.g., a silicon wafer). The carrier substrate 305 is attached to the carrier substrates 145 of the semiconductor dies 150 using an adhesive layer 303. Therefore, the attaching process of the carrier substrate 305 may also be referred to as a wafer-to-wafer bonding process. In some embodiments, the thickness of the carrier substrate 305 is larger than that of the (thinned) carrier substrate 145, and in addition, and the thickness of the (thinned) carrier substrate 145 is larger than that of the (thinned) substrate 101 (or 201).

Next, in FIG. 8, the carrier substrate 245 of the wafer 200 is removed. The process for removing the carrier substrate 245 may be same as or similar to the process for removing the carrier substrate 123, thus details are not repeated. After the removal of the carrier substrate 245, the conductive patterns 237 of the backside interconnect structure 231 are exposed at a surface of the backside interconnect structure 231 distal from the substrate 201.

Next, external connectors 307 (may also be referred to as conductive bumps) are formed on the conductive patterns 237 to provide electrical connection to other device(s). The external connectors 307 may be any suitable type of external contacts, such as controller collapse chip connect (C4) bumps, microbumps, copper pillars, a copper layer, a nickel layer, a lead free (LF) layer, an electroless nickel electroless palladium immersion gold (ENEPIG) layer, a Cu/LF layer, a Sn/Ag layer, a Sn/Pb, combinations of these, or the like.

Next, a dicing process is performed to separate the semiconductor structure 300 into individual (e.g., separate) semiconductor devices 350 (e.g., SoIC devices). The dicing process may be performed along dicing regions indicated by the dashed lines 310 in FIG. 8. The dicing process may start from the backside interconnect structure 231 of the wafer 200 toward the carrier substrate 305. Note that after the dicing process is finished, the wafer 200 is separated into a plurality of semiconductor dies 250. Therefore, the portion of the semiconductor structure 300 illustrated in FIG. 8 between the dashed lines 310 corresponds to a semiconductor device 350. In the example of FIG. 8, the semiconductor device 350 includes a portion of the carrier substrate 305, a semiconductor die 150, and a semiconductor die 250. The number of dies in the semiconductor device 350 illustrated in FIG. 8 (or other disclosed semiconductor devices such as 350A and 450) is merely a non-limiting example, other numbers of dies may be integrated into the semiconductor device, and there may be more than two layers of vertically stacked dies in the semiconductor device, these and other variations are fully intended to be included without the scope of the present disclosure.

As illustrated in FIG. 8, the bonding between the semiconductor die 150 and the semiconductor die 250 is front-side to front-side bonding. Therefore, communication (e.g., exchange of data/control signals) between the semiconductor die 150 and the semiconductor die 250 in the semiconductor device 350 is achieved by conductive paths (also referred to as communication paths) extending through the front-side interconnect structures 112 and 212 and the bonding film stacks 151 and 251. This shortens the communication paths between the semiconductor die 150 and the semiconductor die 250, thus reducing the electrical resistance and signal transmission delay of the communication paths, and increasing the processing speed of the device formed.

To appreciate the advantages, consider a reference design where the bonding structures 154 and 254 of the semiconductor dies 150 and 250 are formed on the backside interconnect structures 132 and 232, respectively. In such a reference design, the semiconductor dies 150 and 250 are bonded by a backside-to-backside bonding, and the front-side interconnect structures 112 and 212 face away from each other. The communication between the semiconductor dies 150 and 250 is achieved by TSVs that extend through, e.g., the front-side interconnect structure 112, the device layer 108, the substrate 101, the backside interconnect structure 132, the bonding film stacks 151, the bonding film stack 251, the backside interconnect structure 232, the substrate 201, the device layer 208, and the front-side interconnect structure 212. The communication paths of the reference design are considerably longer than the disclosed embodiments, thus causing longer signal transmission delay and larger electrical resistance. The disclosed embodiments shorten the communication path considerably, and as a result, reduce the electrical resistance and signal transmission delay.

Another advantage of the disclosed embodiments is the reduced risk of metal cracking due to stress. Compared with the reference design discussed above, the bonding film stack 151 and 251 in the disclosed embodiments herein are thinner (e.g., having a smaller thickness). The smaller thickness of the bonding film stack may result in less stress (e.g., thermal stress and/or mechanical stress) between the bonding structures and the bonding film stack. The stress may be due to, e.g., mismatch in coefficients of thermal expansion (CTEs) during thermal cycles, and/or uneven distribution of stress in thick bonding film stack. The disclosed embodiments, by having thinner bonding film stacks, reduce the risk of metal cracking, thus improving device reliability and production yield.

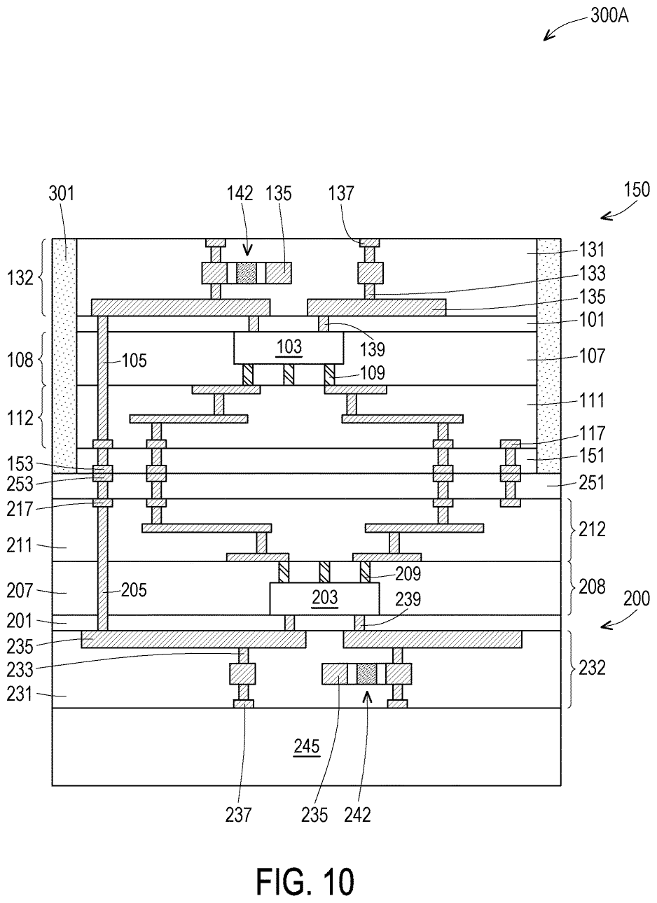

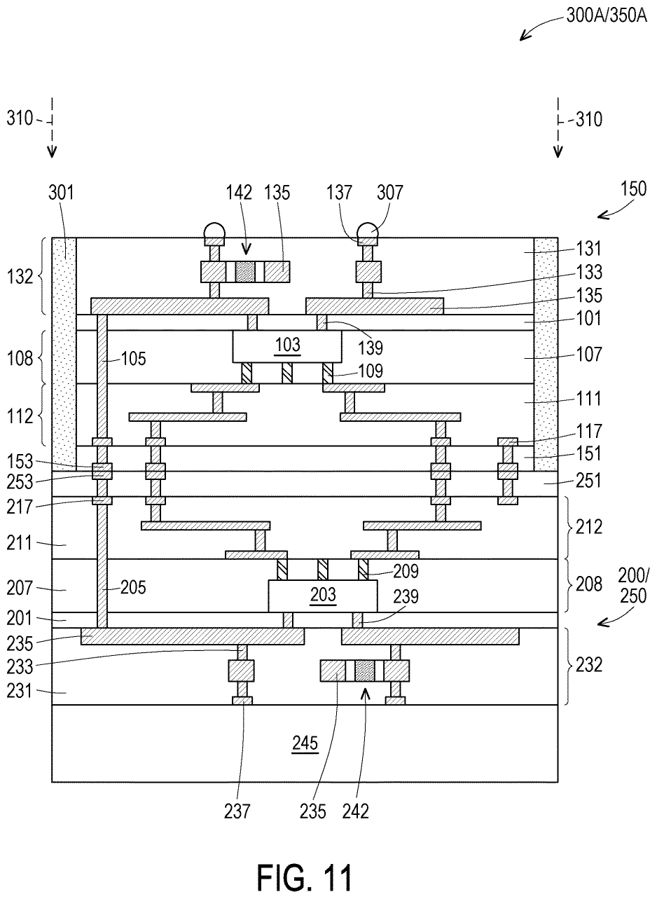

FIGS. 10-11 illustrate cross-sectional views of a semiconductor device 350A at various stages of manufacturing, in accordance with another embodiment. In FIG. 10, the semiconductor dies 150 are attached (e.g., bonded) to the wafer 200 to form a semiconductor structure 300A (e.g., a CoW structure), using the same or similar bonding process for forming the semiconductor structure 300 in FIG. 6. Next, the carrier substrate 145 is removed, using a same or similar carrier substrate removal process as discussed above. Next, the gap-fill material 301 is formed on the wafer 200 around the semiconductor dies 150. A planarization process, such as CMP, may be performed next to remove excess portions of the gap-fill material 301 and to achieve a coplanar surface between the gap-fill material 301 and the semiconductor dies 150. After the planarization process, the conductive patterns 137 of the backside interconnect structure 132 are exposed at the surface of the backside interconnect structure 132 distal from the substrate 101.

Next, in FIG. 11, external connectors 307 are formed on the conductive patterns 137. Next, a dicing process is performed to separate the semiconductor structure 300A into individual (e.g., separate) semiconductor devices 350A (e.g., SoIC devices). The dicing may start from the backside interconnect structure 132 of the semiconductor die 150 toward the carrier substrate 245. The dashed lines 310 in FIG. 11 indicate the dicing regions. The portion of wafer 200 in FIG. 11 between the dashed lines 310 forms a semiconductor die 250 after the dicing process is completed. Therefore, the portion of semiconductor structure 300A between the dashed lines 310 illustrated in FIG. 11 corresponds to a semiconductor device 350A after the dicing process is completed. Each semiconductor device 350A includes a portion of the carrier substrate 245, a semiconductor die 250, and a semiconductor die 150.

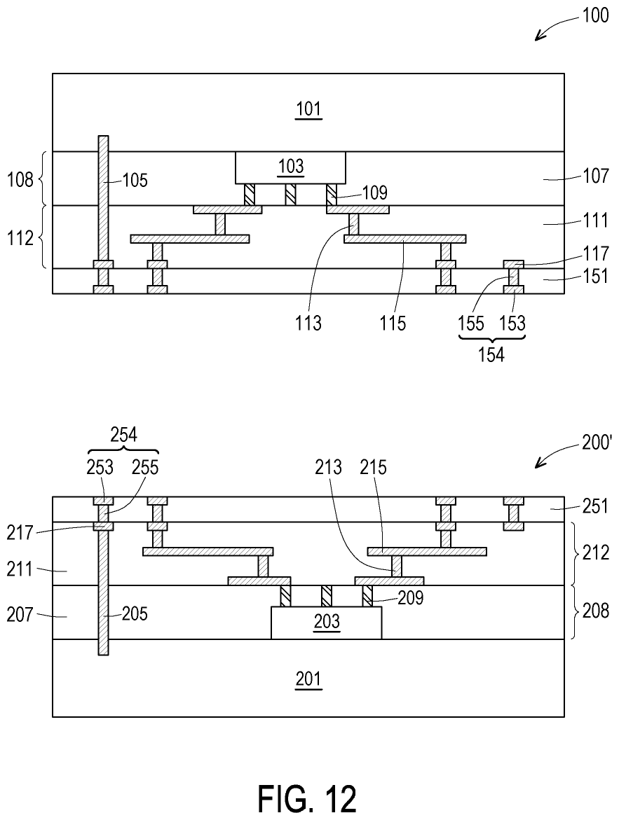

FIGS. 12-16 illustrate cross-sectional views of a semiconductor device 450 at various stages of manufacturing, in accordance with yet another embodiment. In FIG. 12, a wafer 100, which is similar to the wafer 100 of FIG. 1 but with the bonding film stack 151 and the bonding structures 154 formed, is aligned with a wafer 200′, such that bonding pads 153 of the wafer 100 are aligned with respective bonding pads 253 of the wafer 200′. Note that at this stage of processing, the backside interconnect structures 132 of the wafers 100 has not been formed yet. The wafer 200′ in FIG. 12 has a same or similar structure as the wafer 100 in FIG. 12, and corresponds to the wafer 200 in FIG. 5 but without the backside interconnect structure 232 and the carrier substrate 245. In addition, the substrate 201 of the wafer 200′ in FIG. 12 has not been thinned.

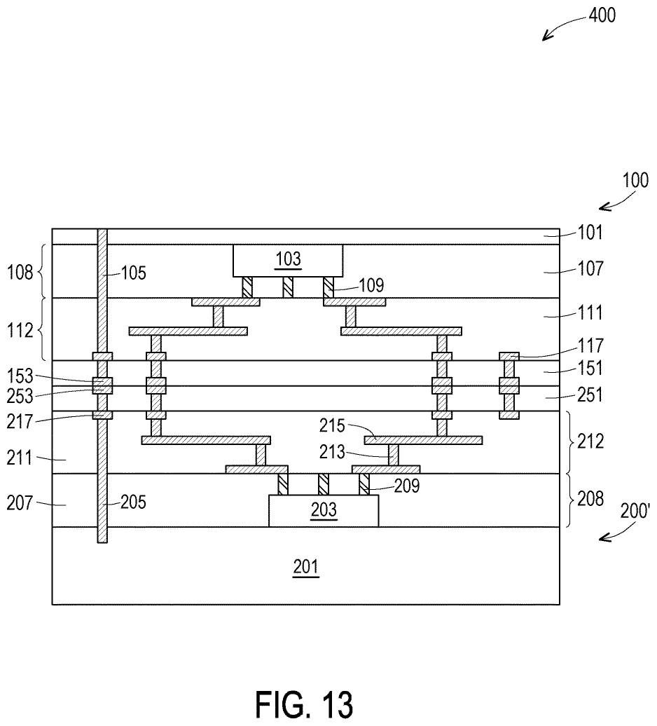

Next, in FIG. 13, the wafer 100 is bonded to the wafer 200′ to form a semiconductor structure 400, e.g., by a direct metal-to-metal bonding and direct dielectric-to-dielectric bonding, although other suitable bonding process may also be used. The semiconductor structure 400 at this stage of processing may be referred to as a Wafer-on-Wafer (WoW) structure. Next, a thinning process is performed to thin the substrate 101, such that end surfaces of the TSVs 105 are exposed at the surface of the substrate 101 distal from the wafer 200′.

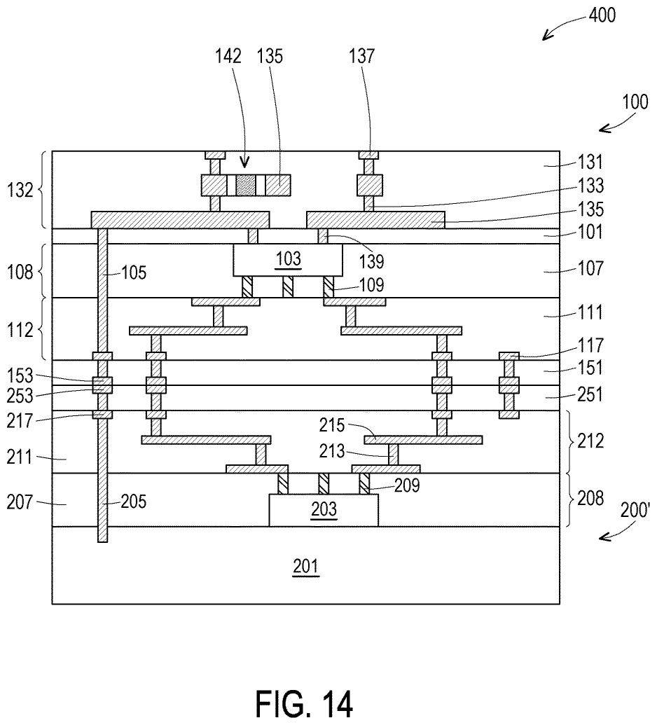

Next, in FIG. 14, the backside interconnect structures 132 are formed on the substrate 101. The backside interconnect structures 132 includes conductive lines 135 and vias 133, and may include integrated MIM capacitors 142. The conductive lines 135 are thicker than the conductive lines 115 of the front-side interconnect structures 112, in some embodiments. Details of the backside interconnect structures 132 are the same as or similar to those discussed above, thus not repeated.

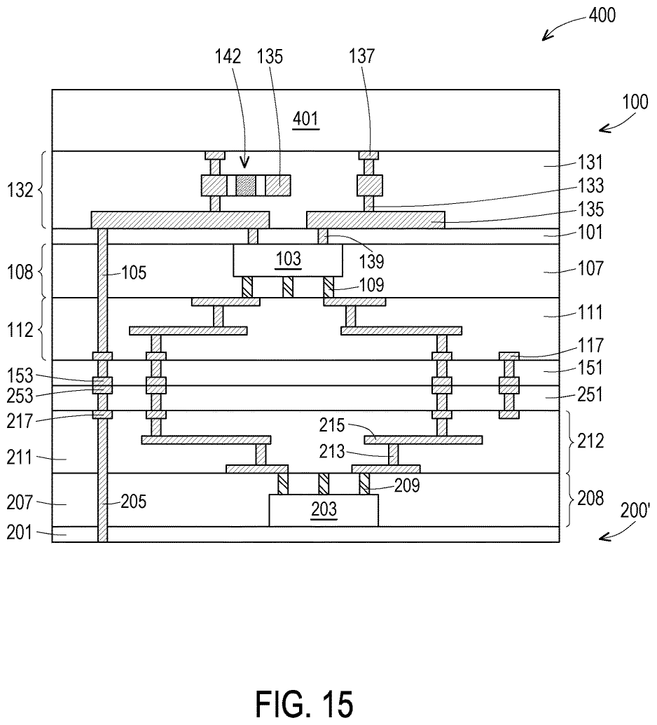

Next, in FIG. 15, a carrier substrate 401 is attached to the backside interconnect structures 132 of the wafer 100. The carrier substrate 401 may be the same as or similar to, e.g., the carrier substrate 145, thus details are not repeated. Next, a thinning process is performed to thin the substrate 201 of the wafer 200′, such that end surfaces of the TSVs 205 are exposed at the surface of the substrate 201 distal from the wafer 100.

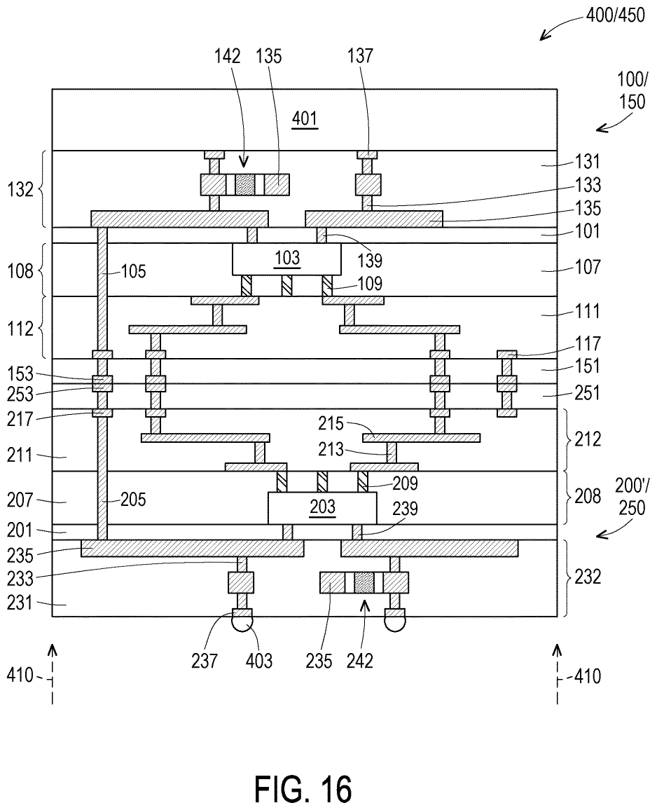

Next, in FIG. 16, the backside interconnect structures 232 of the wafer 200′ are formed on the substrate 201. The backside interconnect structures 232 include conductive lines 235 and vias 233, and may include integrated MIM capacitors 242. The conductive lines 235 are thicker than the conductive lines 215 of the front-side interconnect structures 212, in some embodiments. Details of the backside interconnect structures 232 are the same as or similar to those discussed above, thus not repeated.

Next, external connectors 403 are formed on the conductive patterns 237 exposed at the surface of the backside interconnect structures 232 distal from the substrate 201. Next, a dicing process is performed to separate the semiconductor structure 400 into individual (e.g., separate) semiconductor devices 450 (e.g., SoIC devices). The dicing may start from the backside interconnect structure 232 of the wafer 200′ toward the carrier substrate 401. The dashed lines 410 in FIG. 16 indicate the dicing regions. The portion of wafer 100 in FIG. 16 between the dashed lines 410 forms a semiconductor die 150 after the dicing process is completed. Similarly, the portion of wafer 200′ in FIG. 16 between the dashed lines 410 forms a semiconductor die 250 after the dicing process is completed. Therefore, the portion of semiconductor structure 400 between the dashed lines 410 illustrated in FIG. 16 corresponds to a semiconductor device 450 after the dicing process is completed. Each semiconductor device 450 includes a portion of the carrier substrate 401, a semiconductor die 150, and a semiconductor die 250.

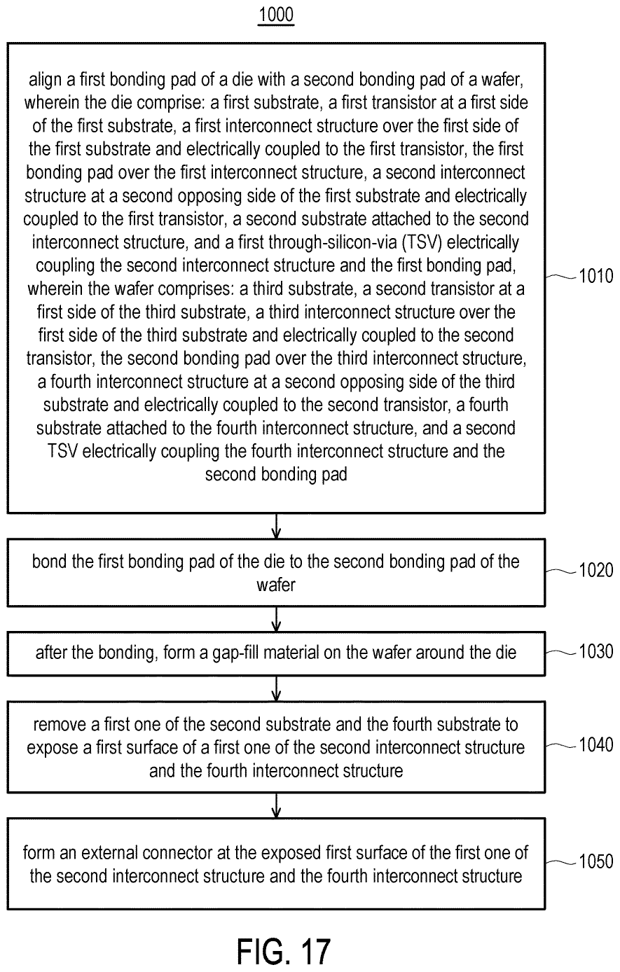

FIG. 17 illustrates a flow chart of a method 1000 of forming a semiconductor device, in some embodiments. It should be understood that the embodiment method shown in FIG. 17 is merely an example of many possible embodiment methods. One of ordinary skill in the art would recognize many variations, alternatives, and modifications. For example, various steps as illustrated in FIG. 17 may be added, removed, replaced, rearranged and repeated.

Referring to FIG. 17, at block 1010, a first bonding pad of a die is aligned with a second bonding pad of a wafer, wherein the die comprise: a first substrate, a first transistor at a first side of the first substrate, a first interconnect structure over the first side of the first substrate and electrically coupled to the first transistor, the first bonding pad over the first interconnect structure, a second interconnect structure at a second opposing side of the first substrate and electrically coupled to the first transistor, a second substrate attached to the second interconnect structure, and a first through-silicon-via (TSV) electrically coupling the second interconnect structure and the first bonding pad, wherein the wafer comprises: a third substrate, a second transistor at a first side of the third substrate, a third interconnect structure over the first side of the third substrate and electrically coupled to the second transistor, the second bonding pad over the third interconnect structure, a fourth interconnect structure at a second opposing side of the third substrate and electrically coupled to the second transistor, a fourth substrate attached to the fourth interconnect structure, and a second TSV electrically coupling the fourth interconnect structure and the second bonding pad. At block 1020, the first bonding pad of the die is bonded to the second bonding pad of the wafer. At block 1030, after the bonding, a gap-fill material is formed on the wafer around the die. At block 1040, a first one of the second substrate and the fourth substrate is removed to expose a first surface of a first one of the second interconnect structure and the fourth interconnect structure. At block 1050, an external connector is formed at the exposed first surface of the first one of the second interconnect structure and the fourth interconnect structure.

Disclosed embodiments achieve various advantages. For example, the disclosed semiconductor device 350, 350A, and 450 are formed by front-side to front-side bonding of the semiconductor dies integrated in the semiconductor device. Compared with a reference design where the semiconductor dies are bonded by a backside-t0-backside bonding, the disclosed embodiments reduce the lengths of the communication paths between the semiconductor dies integrated in the semiconductor device. The shortened communication paths reduce electrical resistance and signal transmission delay, thus achieving faster signal processing. In addition, the bonding film stack of the semiconductor dies integrated in the semiconductor device have reduced thickness compared with the reference design. The thinner bonding film stack advantageously reduces the risk of metal cracking, thus improving device reliability and production yield.

In accordance with an embodiment, a semiconductor device includes a first die that comprises: a first substrate; a first transistor at a first side of the first substrate; a first interconnect structure over the first side of the first substrate and electrically coupled to the first transistor; a first bonding pad over the first interconnect structure; a second interconnect structure at a second side of the first substrate and electrically coupled to the first transistor, wherein the second side of the first substrate opposes the first side of the first substrate; a second substrate attached to a first surface of the second interconnect structure facing away from the first substrate; and a first through-silicon-via (TSV) electrically coupling the second interconnect structure and the first bonding pad. The semiconductor device also includes a second die bonded to the first die, wherein the second die comprises: a third substrate; a second transistor at a first side of the third substrate; a third interconnect structure over the first side of the third substrate and electrically coupled to the second transistor; a second bonding pad over the third interconnect structure, wherein the first bonding pad is bonded to the second bonding pad; a fourth interconnect structure at a second side of the third substrate and electrically coupled to the second transistor, wherein the second side of the third substrate opposes the first side of the third substrate; and a second TSV electrically coupling the fourth interconnect structure and the second bonding pad. The semiconductor device further includes an external connector attached to a conductive feature of the fourth interconnect structure, wherein the conductive feature is at a first surface of the fourth interconnect structure facing away from the third substrate. In an embodiment, the semiconductor device further includes a gap-fill material around and contacting the first die, wherein sidewalls of the first die are covered by the gap-fill material, and sidewalls of the second die are exposed by the gap-fill material. In an embodiment, an exterior sidewall of the gap-fill material facing away from the first die is aligned with a respective sidewall of the second die along a same line. In an embodiment, the semiconductor device further includes a fourth substrate attached to the second substrate and the gap-fill material, wherein the first die is interposed between the fourth substrate and the second die. In an embodiment, the semiconductor device further includes a gap-fill material around and contacting the second die, wherein sidewalls of the second die are covered by the gap-fill material, and sidewalls of the first die are exposed by the gap-fill material. In an embodiment, an exterior sidewall of the gap-fill material facing away from the second die is aligned with a respective sidewall of the first die along a same line. In an embodiment, a first width of the first die, measured between opposing sidewalls of the first die, is the same as a second width of the second die measured between opposing sidewalls of the second die. In an embodiment, the first substrate, the second substrate, and the third substrate are silicon substrates. In an embodiment, the second substrate is thicker than the first substrate and the third substrate. In an embodiment, conductive lines of the second interconnect structure are thicker than conductive lines of the first interconnect structure. In an embodiment, the second interconnect structure comprises a first capacitor, wherein the first capacitor comprises: a first barrier layer extending along a first sidewall of a first conductive line of the second interconnect structure; a second barrier layer extending along a second sidewall of a second conductive line of the second interconnect structure laterally adjacent to the first conductive line, wherein the second sidewall faces the first sidewall; and a high-K dielectric material extending from the first barrier layer to the second barrier layer.

In accordance with an embodiment, a semiconductor device includes a first die that comprises: a first substrate; first electrical components at a first side of the first substrate; a first interconnect structure at the first side of the first substrate and electrically coupled to the first electrical components; a second interconnect structure at a second side of the first substrate and electrically coupled to the first electrical components, wherein the second side of the first substrate opposes the first side of the first substrate; a second substrate attached to the second interconnect structure, wherein the second interconnect structure is interposed between the second substrate and the first substrate; a first bonding film stack on the first interconnect structure, wherein the first interconnect structure is between the first bonding film stack and the first substrate; first bonding structures embedded in the first bonding film stack; and a first through-silicon-via (TSV) extending from the second interconnect structure to the first bonding structures. The semiconductor device also includes a second die bonded to the first die, wherein the second die comprises: a third substrate; second electrical components at a first side of the third substrate; a third interconnect structure at the first side of the third substrate and electrically coupled to the second electrical components; a fourth interconnect structure at a second side of the third substrate and electrically coupled to the second electrical components, wherein the second side of the third substrate opposes the first side of the third substrate; a second bonding film stack on the third interconnect structure, wherein the third interconnect structure is between the second bonding film stack and the third substrate; second bonding structures embedded in the second bonding film stack, wherein the second bonding structures are bonded to respective ones of the first bonding structures; and a second TSV extending from the fourth interconnect structure to the second bonding structures. The semiconductor device further includes external connectors bonded to conductive features at a surface of the fourth interconnect structure facing away from the third substrate. In an embodiment, a first width of the first bonding film stack, measured between opposing sidewalls of the first bonding film stack, is smaller than a second width of the second bonding film stack measured between opposing sidewalls of the second bonding film stack. In an embodiment, the semiconductor device further includes a gap-fill material around the first die, wherein the gap-fill material contacts and extends along sidewalls of the first bonding film stack and a surface of the second bonding film stack facing the first bonding film stack. In an embodiment, the semiconductor device further includes a fourth substrate attached to the second substrate and the gap-fill material, wherein a third width of the fourth substrate, measured between opposing sidewalls of the fourth substrate, is the same as the second width of the second bonding film stack. In an embodiment, each of the first bonding structures comprises a first bonding pad and a first bonding pad via (BPV), wherein the first BPV electrically couples the first bonding pad to the first interconnect structure, wherein each of the second bonding structures comprises a second bonding pad and a second BPV, wherein the second BPV electrically couples the second bonding pad to the third interconnect structure, wherein the first bonding pad of each of the first bonding structures is bonded to a second bonding pad of a respective one of the second bonding structures.

In accordance with an embodiment, a method of forming a semiconductor device includes aligning a first bonding pad of a die with a second bonding pad of a wafer, wherein the die comprise: a first substrate, a first transistor at a first side of the first substrate, a first interconnect structure over the first side of the first substrate and electrically coupled to the first transistor, the first bonding pad over the first interconnect structure, a second interconnect structure at a second opposing side of the first substrate and electrically coupled to the first transistor, a second substrate attached to the second interconnect structure, and a first through-silicon-via (TSV) electrically coupling the second interconnect structure and the first bonding pad, wherein the wafer comprises: a third substrate, a second transistor at a first side of the third substrate, a third interconnect structure over the first side of the third substrate and electrically coupled to the second transistor, the second bonding pad over the third interconnect structure, a fourth interconnect structure at a second opposing side of the third substrate and electrically coupled to the second transistor, a fourth substrate attached to the fourth interconnect structure, and a second TSV electrically coupling the fourth interconnect structure and the second bonding pad. The method further includes: bonding the first bonding pad of the die to the second bonding pad of the wafer; after the bonding, forming a gap-fill material on the wafer around the die; removing a first one of the second substrate and the fourth substrate to expose a first surface of a first one of the second interconnect structure and the fourth interconnect structure; and forming an external connector at the exposed first surface of the first one of the second interconnect structure and the fourth interconnect structure. In an embodiment, the method further includes, after forming the external connector, performing a dicing process along dicing regions around the die. In an embodiment, the method further includes, after forming the gap-fill material and before the removing, attaching a fifth substrate to the second substrate and the gap-fill material. In an embodiment, the removing comprises removing the fourth substrate to expose the first surface of the fourth interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
receiving a first die, wherein the first die comprises:
a first substrate having a first side and a second side opposite the first side;
a first transistor at the first side of the first substrate;
a first front-side interconnect structure at the first side of the first substrate and electrically coupled to the first transistor;
a first bonding film stack on the first front-side interconnect structure;
a first bonding pad and a first bonding pad via (BPV) that are embedded in the first bonding film stack;
a first backside interconnect structure at the second side of the first substrate;
a first through-silicon-via (TSV) extending through the first substrate and electrically coupling the first bonding pad to the first backside interconnect structure; and
a second substrate attached to the first backside interconnect structure;
moving the first die over a wafer, wherein the wafer comprises a second die, wherein the second die comprises:
a third substrate having a first side and a second side opposite the first side of the third substrate;
a second transistor at the first side of the third substrate;
a second front-side interconnect structure at the first side of the third substrate and electrically coupled to the second transistor;
a second bonding film stack on the second front-side interconnect structure;
a second bonding pad and a second BPV that are embedded in the second bonding film stack;
a second backside interconnect structure at the second side of the third substrate;
a second TSV extending through the third substrate and electrically coupling the second bonding pad to the second backside interconnect structure; and
a fourth substrate attached to the second backside interconnect structure;
aligning the first bonding pad of the first die with the second bonding pad of the second die;
bonding the first die to the wafer, wherein bonding the first die comprises bonding the first bonding pad to the second bonding pad through direct metal-to-metal bonding;
after the bonding, thinning the second substrate of the first die;
after the thinning, forming a gap-fill material on the wafer and around the first die;
attaching a fifth substrate to the gap-fill material and the thinned second substrate of the first die; and
after the attaching the fifth substrate, removing the fourth substrate of the second die to expose a surface of the second backside interconnect structure.

2. The method of claim 1, wherein bonding the first die to the wafer further comprises bonding the first bonding film stack to the second bonding film stack through direct dielectric-to-dielectric bonding.

3. The method of claim 1, further comprising forming the first die, wherein the forming the first die comprises:
forming the first transistor at the first side of the first substrate;
forming the first front-side interconnect structure over the first side of the first substrate;
forming the first TSV extending through the first front-side interconnect structure and into the first substrate;
attaching a sixth substrate to the first front-side interconnect structure;
after attaching the sixth substrate, thinning the first substrate from the second side to expose the first TSV;
after the thinning, forming the first backside interconnect structure at the second side of the first substrate and electrically coupled to the first TSV;
after forming the first backside interconnect structure, attaching the second substrate to the first backside interconnect structure;
after attaching the second substrate, removing the sixth substrate to expose the first front-side interconnect structure; and
after removing the sixth substrate, forming the first bonding pad, the first BPV, and the first bonding film stack on the first front-side interconnect structure.

4. The method of claim 1, further comprising, after removing the fourth substrate, forming an external connector on the exposed surface of the second backside interconnect structure.

5. The method of claim 4, wherein the wafer further comprises a plurality of third dies, wherein the method further comprises, after forming the external connector, performing a dicing process along dicing regions of the wafer to separate the second die from the plurality of third dies.

6. The method of claim 1, wherein the first backside interconnect structure comprises first dielectric layers and first conductive lines embedded in the first dielectric layers, wherein the first conductive lines comprise a first conductive line and a second conductive line that are embedded in a same dielectric layer of the first dielectric layers and laterally adjacent to each other, wherein the first backside interconnect structure further comprises a first capacitor interposed between the first conductive line and the second conductive line, wherein the first capacitor comprises:
a first barrier layer along a first sidewall of the first conductive line facing the second conductive line;
a second barrier layer along a second sidewall of the second conductive line facing the first conductive line; and
a high-K dielectric material extending continuously from the first barrier layer to the second barrier layer.

7. The method of claim 6, wherein the first front-side interconnect structure comprises second dielectric layers and second conductive lines embedded in the second dielectric layers, wherein the first conductive lines of the first backside interconnect structure are wider than the second conductive lines of the first front-side interconnect structure.

8. The method of claim 6, wherein the second backside interconnect structure comprises second dielectric layers, second conductive lines embedded in the second dielectric layers, and a second capacitor.

9. The method of claim 1, wherein the gap-fill material extends along and contacts sidewalls of the first bonding film stack and a surface of the second bonding film stack facing the first die.

10. The method of claim 1, wherein the first bonding film stack comprises a plurality of dielectric layers, and adjacent layers of the plurality of dielectric layers are formed of different dielectric materials, wherein the first bonding pad extends through two or more of the plurality of dielectric layers, and the first BPV extends through another two or more of the plurality of dielectric layers.

11. The method of claim 10, wherein the first bonding pad is coupled to a conductive pattern of the first front-side interconnect structure by the first BPV, wherein a ratio of a width of the first BPV to a width of the conductive pattern is between about 0.025 and about 1.

12. A method of forming a semiconductor device, the method comprising:
receiving a die, wherein the die comprises a first substrate, a first transistor at a first side of the first substrate, a first front-side interconnect structure at the first side of the first substrate and electrically coupled to the first transistor, a first bonding film stack on the first front-side interconnect structure, a first bonding structure embedded in the first bonding film stack, a first backside interconnect structure at a second opposing side of the first substrate, a second substrate attached to the first backside interconnect structure, and a first through-silicon-via (TSV) electrically coupling the first backside interconnect structure and the first bonding structure;
aligning the first bonding structure of the die with a second bonding structure of a wafer, wherein the wafer comprises: a third substrate, a second transistor at a first side of the third substrate, a second front-side interconnect structure at the first side of the third substrate and electrically coupled to the second transistor, a second bonding film stack on the second front-side interconnect structure, the second bonding structure embedded in the second bonding film stack, a second backside interconnect structure at a second opposing side of the third substrate, a fourth substrate attached to the second backside interconnect structure, and a second TSV electrically coupling the second backside interconnect structure and the second bonding structure;
bonding the first bonding structure of the die to the second bonding structure of the wafer;
after the bonding, forming a gap-fill material on the wafer and around the die;
removing a first one of the second substrate and the fourth substrate to expose a first surface of a first one of the first backside interconnect structure and the second backside interconnect structure; and
forming an external connector at the exposed first surface of the first one of the first backside interconnect structure and the second backside interconnect structure.

13. The method of claim 12, further comprising, after forming the external connector, dicing the wafer along dicing regions of the wafer, wherein in a top view, the die is surrounded by the dicing regions.

14. The method of claim 12, wherein the removing comprises removing the fourth substrate to expose the first surface of the second backside interconnect structure.

15. The method of claim 14, further comprising, after forming the gap-fill material and before the removing, attaching a fifth substrate to the second substrate and the gap-fill material.

16. The method of claim 12, wherein the removing comprises removing the second substrate to expose the first surface of the first backside interconnect structure.

17. A semiconductor device comprising:
a first die comprising:
a first substrate;
a first transistor at a first side of the first substrate;
a first front-side interconnect structure at the first side of the first substrate and electrically coupled to the first transistor;
a first bonding film stack on the first front-side interconnect structure;
a first bonding structure embedded in the first bonding film stack;
a first backside interconnect structure at a second side of the first substrate, wherein the second side of the first substrate opposes the first side of the first substrate;
a second substrate attached to a first surface of the first backside interconnect structure facing away from the first substrate; and
a first through-silicon-via (TSV) electrically coupling the first backside interconnect structure and the first bonding structure;
a second die bonded to the first die, wherein the second die comprises:
a third substrate;
a second transistor at a first side of the third substrate;
a second front-side interconnect structure at the first side of the third substrate and electrically coupled to the second transistor;
a second bonding film stack on the second front-side interconnect structure;
a second bonding structure embedded in the second bonding film stack, wherein the first bonding structure is bonded to the second bonding structure through direct metal-to-metal bonding, and the first bonding film stack is bonded to the second bonding film stack through direct dielectric-to-dielectric bonding;
a second backside interconnect structure at a second side of the third substrate, wherein the second side of the third substrate opposes the first side of the third substrate; and
a second TSV electrically coupling the second backside interconnect structure and the second bonding structure;
a gap-fill material extending along and contacting sidewalls of the first die, wherein sidewalls of the second die are free of the gap-fill material; and
an external connector attached to a conductive feature of the second backside interconnect structure, wherein the conductive feature is at a second surface of the second backside interconnect structure facing away from the first die.

18. The semiconductor device of claim 17, further comprising a fourth substrate attached to the second substrate and the gap-fill material, wherein the first die is interposed between the fourth substrate and the second die, wherein the first substrate and the second substrate have a first width, wherein the third substrate and the fourth substrate have a second width larger than the first width.

19. The semiconductor device of claim 18, wherein an exterior sidewall of the gap-fill material facing away from the first die is aligned with a respective sidewall of the second die along a same line.

20. The semiconductor device of claim 18, wherein the second substrate is thicker than the first substrate and the third substrate.
